(19) United States
(12) Patent Application Publication
(10) Pub. No.: US 2005/0059235 A1
(43) Pub. Date: Mar. 17, 2005

(54) Method for improving oxide layer flatness

(76) Inventors: Been-Jon Woo, Shanghai (CN); Mon-Chin Tsai, Shanghai (CN)

Correspondence Address: ROSENBERG, KLEIN & LEE, 3458 ELLICOTT CENTER DRIVE-SUITE 101, ELLICOTT CITY, MD, 21043, US

(21) Appl. No.: 10/918,434

(22) Filed: Aug. 16, 2004

(30) Foreign Application Priority Data
Aug. 27, 2003 (CN) 03150598.8

(51) Int. Cl. H01L 21/8242; H01S 3/08; H01L 21/4763

(52) U.S. Cl. 438/633; 438/635

(57) ABSTRACT

A method for improving the flatness of an oxide layer comprising the steps of providing a semiconductor structure, forming a polysilicon layer on the semiconductor structure, utilizing chemical mechanical polishing to planarize the polysilicon layer, and forming an oxide layer on the polysilicon layer. As a result of using chemical mechanical polishing on the polysilicon layer, an improved flatness of the subsequently formed oxide layer is achieved.

### BACKGROUND OF THE INVENTION

1. Field of the Invention

The present invention generally relates to a method for treating a polysilicon layer, and more particularly relates to a method for treating a polysilicon layer to improve the formulation of an oxide layer with improved flatness.

2. Description of the Prior Art

Chemical Mechanical Polishing (CMP) technology plays a decisive role in semiconductor manufacturing. CMP utilizes suitable chemical additives so as to polish the rising and falling profile of the wafer surface to obtain a flat surface. Once the parameters of CMP processing are appropriately controlled, CMP technology can provide a flatness level of over 94%, for the polished surface.

However, it is very difficult to control the planarization processing of CMP technology. The main reason for this is the understanding of CMP processing, which combines chemical reactions and mechanical polishing, is still in a developing stage. Hence, the development of CMP technology has proceeded with difficultly and as a result, CMP technology is commonly used in the planarization of multi-interconnections.

In view of the continually decreasing critical dimension (CD) of the process, the flatness requirements have become more and more important. If the formed oxide layer is as flat as possible, it is more useful for the following processes.

Therefore there is need for an improved method of improving oxide layer flatness.

### SUMMARY OF THE INVENTION

In view of the requirements for preferred flatness, an objective of the present invention is to provide a method for forming a flat oxide layer. The present invention utilizes a step of treating the surface before forming the oxide layer so as to improve the flatness of the subsequently formed oxide layer.

Another object of the present invention is to provide a method for improving the capacitance quality. The present invention utilizes chemical mechanical polishing technology to treat the polysilicon layer so as to achieve the preferred formulation of the capacitance elements.

In order to achieve previous objects, the present invention generally relates to providing a method for improving the flatness of the formed oxide layer. The present invention comprises the steps of providing a semiconductor structure, forming a polysilicon layer on the semiconductor structure, utilizing a chemical mechanical polishing -process to treat the polysilicon layer, and forming an oxide layer on the polysilicon layer.

These and other objectives of the present invention will become obvious to those of ordinary skill in the art after reading the following detailed description of preferred embodiments.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1A and FIG. 1B are drawings illustrating a partial cross-section of a polysilicon layer in accordance with an embodiment of the present invention.

### DESCRIPTION OF THE PREFERRED EMBODIMENTS

Reference will now be made in detail to the preferred embodiments of the present invention, examples of which are illustrated in the accompanying drawings. Wherever possible, the same reference numbers are used in the drawings and the description to refer to the same or like parts.

The present invention can be utilized in a wide variety of semiconductor designs using various semiconductor materials.

The drawings and discussion herein comprise a few specific embodiments with the understanding that the present disclosure is to be considered only as an exemplification of the principles of the present invention, and many alternative, modifications and variations will be apparent to those skilled in the art and it is intended to embrace all such alternatives, modifications and variations that fall within the spirit and scope of the present invention.

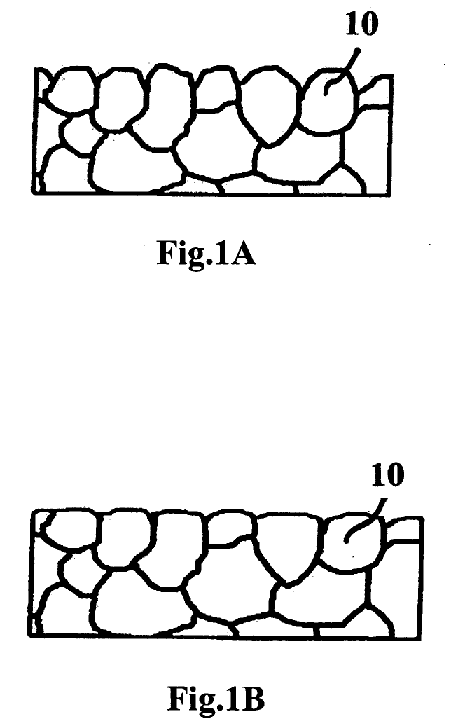

Refer to FIG. 1A and FIG. 1B, which are drawings illustrating a partial cross-section of a polysilicon layer in accordance with an embodiment of the present invention.

As shown in FIG. 1A, a polysilicon layer is formed on a semiconductor structure, wherein the thickness of the polysilicon layer is about 500 to 5,000 angstroms. According to the shape and the arrangement of the polysilicon molecules 10, the surface of the polysilicon layer results in a rugged surface with poor flatness. The rugged surface will highly influence the formulation of other layers in the following processes.

The present invention utilizes chemical mechanical polishing technology to planarize the surface of the polysilicon layer. In one preferred embodiment of the present invention, the thickness of the polysilicon layer removed by the chemical mechanical polish is about 500 to 3,000 angstroms so that the rugged surface becomes flatter than a normal polysilicon layer. The improved flatness is shown in the FIG. 1B. Owing to the chemical mechanical polishing of the present invention as used on the polysilicon layer, the chemical conditions and the mechanical parameters of the chemical mechanical polishing should be appropriately adjusted to planarize the surface of the polysilicon layer without excess consumption of the polysilicon layer.

In an embodiment of the present invention, a formulation of a capacitance element is used as an example. An oxide layer is formed on a polysilicon layer, and then an electrode material is formed on the oxide layer. The formulation of the oxide layer can be achieved by oxidizing the polysilicon layer or utilizing chemical vapor deposition (CVD) to form the oxide layer. Owing to the fact that the polysilicon layer is provided with a preferred flatness after the chemical mechanical polishing, the subsequent formulation of the oxide layer can also be provided with a preferred flatness. In the subsequent deposition of a dielectric layer, the surface of the dielectric layer can achieve an improved flatness. Hence, the present invention can provide a higher quality capacitance element.

In summary, the invention provides a method for improving the quality of a capacitance element. The present invention comprises the steps of providing a semiconductor structure, forming a polysilicon layer on the semiconductor structure, utilizing chemical mechanical polishing technology to planarize the polysilicon layer, forming an oxide layer on the polysilicon layer, and depositing a electrode material on the oxide layer.

It will be apparent to those skilled in the art that various modifications and variations can be made to the present invention without departing from the scope or spirit of the invention. In view of the foregoing, it is intended that the present invention cover modifications and variations of this invention provided they fall within the scope of the invention and its equivalent.

1. A method for improving flatness of an oxide layer comprising:
providing a semiconductor structure;
forming a polysilicon layer on the semiconductor structure;
utilizing a chemical mechanical polishing process to treat the polysilicon layer; and
forming an oxide layer on the polysilicon layer.

2. The method of claim 1, the oxide layer being formed by oxidizing the polysilicon layer.

3. The method of claim 1, the oxide layer being formed by chemical vapor depositing processing.

4. The method of claim 1, the polysilicon layer being formed by chemical vapor depositing process.

5. A method for improving quality of a capacitance element comprising:
providing a semiconductor structure;
forming a polysilicon layer on the semiconductor structure;
utilizing a chemical mechanical polishing process to treat the polysilicon layer;
forming an oxide layer on the polysilicon layer; and
depositing an electrode material on the oxide layer.

6. The method of claim 5, the oxide layer being formed by oxidizing the polysilicon layer.

7. The method of claim 5, the oxide layer being formed by chemical vapor depositing processing.

8. The method of claim 5, the polysilicon layer being formed by chemical vapor depositing processing.

9. A method for improving quality of a capacitance element comprising:
providing a semiconductor structure;
using chemical vapor deposition to form a polysilicon layer on the semiconductor structure;
utilizing chemical mechanical polishing to treat the polysilicon layer;
forming an oxide layer on the polysilicon layer by oxidizing the polysilicon layer; and
depositing an electrode material on the oxide layer;
wherein the chemical mechanical polishing improves flatness of the oxide layer.
